(19) United States
(12) Patent Application Publication
(10) Pub. No.: US 2025/0258981 A1
(43) Pub. Date: Aug. 14, 2025

(54) WELLBORE DYNAMIC KILL SIMULATION

(71) Applicant: Landmark Graphics Corporation, Houston, TX (US)

(72) Inventors: Zhengchun Michael Liu, Houston, TX (US); Robello Samuel, Houston, TX (US)

(21) Appl. No.: 18/781,761

(22) Filed: Jul. 23, 2024

Related U.S. Application Data
(60) Provisional application No. 63/551,257, filed on Feb. 8, 2024.

(51) Int. Cl. G06F 30/28; E21B 47/00

(52) U.S. Cl. CPC G06F 30/28; E21B 47/00; E21B 2200/20

(57) ABSTRACT

A method comprises retrieving attributes of a blowout well and a relief well and simulating a dynamic kill of a blowout from the blowout well via a kill mud pumped down through the relief well, wherein the simulating comprises determining a flowing bottom hole pressure for the blowout well and the relief well based on an intersection of a reservoir inflow performance relationship (IPR) curve and a wellbore vertical lift (VLP) curve.

### BACKGROUND

A wellbore blowout may represent one of the largest risks associated with exploration and recovery of hydrocarbons from a subsurface formation. A dynamic kill is a technique that includes a static head of a kill fluid combined with frictional pressure losses in order to suppress the reservoir pressure to kill the blowout. For a harsh, vulnerable environment and deepwater drilling, it is essential to simulate the blowout and dynamic kill in planning and contingency procedures to predict any risks and minimize or avoid blowout events.

During a dynamic kill, multiphase flow of the mixture of mud and hydrocarbon is involved. It is complicated and slow to calculate the pressure profile in the blowout well since the mud front and the flowing bottom hole pressure are changing with the pump rate.

### BRIEF DESCRIPTION OF THE DRAWINGS

Embodiments of the disclosure may be better understood by referencing the accompanying drawings.

FIG. 1 is a schematic diagram of an example relief wellbore intersecting a target wellbore for killing the target wellbore in response to a blowout in the target wellbore, according to some embodiments.

FIG. 2 is a block diagram of an example computer, according to some embodiments.

FIG. 3 is a diagram of an actual versus (vs.) model of mixed fluid elements in a blowout well during a dynamic well kill, according to some embodiments.

FIGS. 4-5 are flowcharts for simulating a flow bottom hole pressure (BHP) versus time during a dynamic well kill, according to some embodiments.

FIG. 6 is a graph depicting a flow BHP vs. time and pump rate vs. time during a dynamic well kill, according to some embodiments.

FIG. 7 is a graph depicting a gas rate vs. a flowing BHP during a simulation of a dynamic well kill, according to some embodiments.

FIG. 8 is a diagram of a model of the pressure of blowout well during a dynamic well kill, according to some embodiments.

FIGS. 9-10 are flowcharts for determining a flow BHP using reservoir inflow performance relationship (IPR) IPR data and a blowout well production operation, according to some embodiments.

FIG. 11 is an example of a graphical user interface (GUI) of an example data for a blowout well configuration, according to some embodiments.

FIG. 12 is a table of example parameters for a dynamic kill operation, according to some embodiments.

FIG. 13 is a table of example attributes of the reservoir, according to some embodiments.

FIG. 14 is an example summary table of a well kill solution, according to some embodiments.

### DESCRIPTION

The description that follows includes example systems, methods, techniques, and program flows that embody aspects of the disclosure. However, it is understood that this disclosure may be practiced without these specific details. In some instances, well-known instruction instances, protocols, structures, and techniques have not been shown in detail in order not to obfuscate the description.

Example implementations relate to dynamic kill wellbore operations that are in response to a wellbore blowout (that results in sudden, uncontrolled release of fluids, primarily oil and gas, from a wellbore during drilling or production operations). Example implementations may include generation of a series of plots showing the changing operation parameters during a dynamic wellbore kill. Examples of such operation parameters may include the flowing bottomhole pressure versus (vs.) time, blowout flow rate vs. time, pump rate vs. time, etc.

In some implementations, to simplify the calculation, the hydrocarbon/mud mixed fluid column may be divided into many small elements. Each element may correspond to the mixed fluid volume formed in a certain time step (e.g., 30 seconds). Inside each element, the kill fluid volume percentage may be assumed to be uniformly distributed.

In some implementations, the flow bottomhole pressure (BHP) may be approximately estimated based on the equilibrium of reservoir fluid in-flow (IPR) and wellbore vertical lift (VLP). For example, a first flowing BHP (BHP1) from a VLP simulation may be based on the pressure profiles of the aforementioned fluid elements, while a second flowing BHP (BHP2) from IPR may be calculated through interpolation using the input table of BHP vs. hydrocarbon flow rate. For a certain time step, the corresponding blowout flow rate may be found via iteration until BHP1=BHP2. Also, a pump rate reduction rate may be used to control the flowing BHP. Pump capacity and formation fracture pressure may also be considered for pump rate reduction.

Some implementations may include an enhanced rock weathering (ERW) model in the thermal flow engine to handle multiple entries of production fluids in the blowout well (such as kill mud entry, reservoir fluid entries, etc.). Some implementations may include a mixed fluid element model of kill mud and hydrocarbons coupled with a multiphase flow model. Additionally, some implementations may include a flowing BHP control by applying the limits of reservoir pressure, formation fracture pressure, and pump capacity.

Accordingly, example implementations may include accurate temperature and pressure profiles, a comprehensive kill fluid inventory including water-based mud and brines, and an engine module that may be friendly to microservice deployment.

### Example System

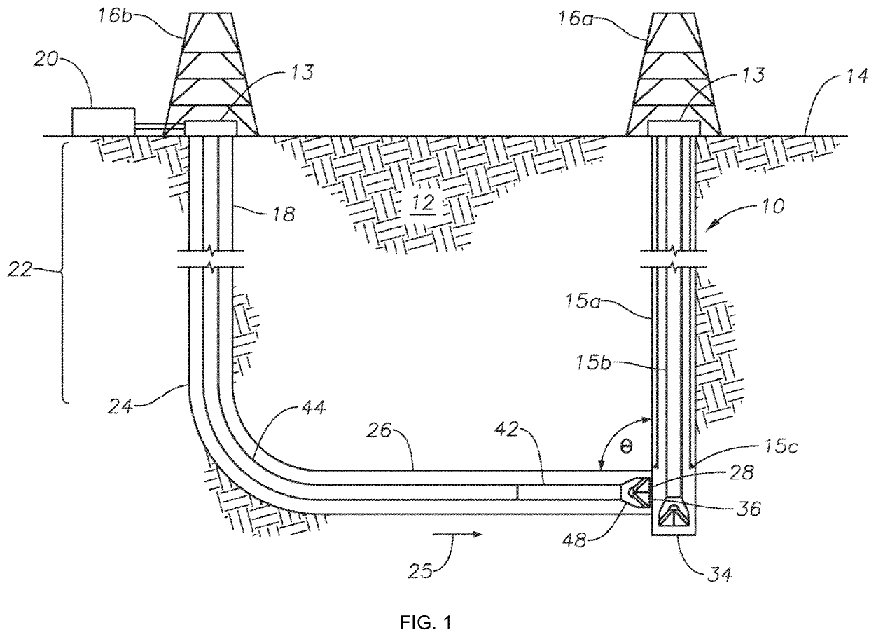

FIG. 1 is a schematic diagram of an example relief wellbore intersecting a target wellbore for killing the target wellbore in response to a blowout in the target wellbore, according to some embodiments. With reference to FIG. 1, a first or target wellbore 10 is shown in a formation 12 extending from a well head 13 at the surface 14. Although first wellbore 10 may have any orientation, for purposes of the discussion, first wellbore 10 is illustrated as extending substantially vertically from the surface 14. To the extent first wellbore 10 is in the process of being drilled, a drilling structure 16 a may be associated with first wellbore 10. The first wellbore 10 may include a conductive body 15, such as casing 15a, a drill string 15b, a casing shoe 15c or other metal component, composite or similar type tubulars. The well head 13 may generally include one or more of blow out preventers, chokes, valves, annular and ram blowout preventers, etc.

A second or relief wellbore 18 is also shown in the formation 12 extending from a well head 13 associated with a drilling structure 16b. Drilling structure 16 b may be the same or a different drilling structure from drilling structure 16a. Drilling structures 16a, 16b are for illustrative purposes only and may be any type of drilling structure utilized to drill a wellbore, including land deployed drilling structures or marine deployed drilling structures. In this regard, the wellbores may extend from land or may be formed at the bottom of a body of water (not shown). In the illustrated embodiment, the first wellbore 10 includes a distal or terminus end 34 and the second wellbore 18 includes a distal or terminus end 36. Also illustrated is a fluid source 20 for fluid introduced into the second wellbore 18.

In this example, the second wellbore 18 is drilled to have a substantially vertical portion 22 extending from surface 14, a kickoff point 24 and a deviated portion 26 extending from the kickoff point 24 along a select trajectory 25. In FIG. 1, the deviated portion 26 is substantially horizontal. The trajectory 25 of this deviated portion 26 is selected to intersect the first wellbore 10 at an intersection point 28 so as to form an angle θ between the first wellbore 10 and the second wellbore 18. The angle θ may be at any of a number of angles.

In some implementations, angle θ may be approximately 90 degrees as shown in FIG. 1, such that the deviated portion 26 is substantially horizontal and second wellbore 18 is substantially J-shaped. While the illustrated embodiment of FIG. 1 is substantially j-shaped, i.e., θ is approximately 90 degrees, in some implementations, angle θ may be greater than 45 degrees. In some implementations, angle θ may be greater than 90 degrees. In some implementations, angle θ may be between 90 and 180 degrees. In some implementations, angle θ may be approximately 180 degrees, such that the relief well approaches the intersection point 28 from below.

FIG. 1 generally illustrates a drill string 44 used to drill the second wellbore 18. The drill string 44 may include a bottom hole assembly 42 having a drill bit 48. The first wellbore 10 may be open hole or include a casing string or liner. Likewise, the second wellbore 18 may be open hole or include a casing string or liner.

The second wellbore 18 may be drilled and cased to an equivalent true vertical depth (“TVD”) as the first wellbore 10, left open hole, or cased off higher than the first wellbore 10. The selection of a particular arrangement, i.e., a relief well drilled from below the intersection point 28 or a relief well with an angle θ is greater than 45 or 90 degrees or a relief well with an obtuse angle θ, is based on whichever intercepting wellpath design is decided upon with the maximum dogleg allowable, based on factors particular to the relief well being drilled, such as, among other things, predicted torque and drag, available surface weight, BHA design, casing wear, drillstring buckling and cuttings removal to consider, all of which are exacerbated by high doglegs.

The intersection point 28 may therefore be in open hole or through a cased portion of the first wellbore 10, where casing herein is understood to include or comprise any and all tubular members; a conduit, a pipe, a casing string, a liner, a slotted liner, coiled tubing, sand screens or the like. Fluid communication between the two wellbores 10, 18 may be established at the intersection point 28. In some implementations, the conductive body 15, such as casing 15a, a drill string 15b, a casing shoe 15c may be adjacent the intersection point 28, and utilized to guide second wellbore 18 to the intersection point 28. For example, as shown in FIG. 1, the intersection point 28 is adjacent casing shoe 15c.

While FIG. 1 and the following description is in reference to one relief well, example implementations may include more than one relief well. For example, a first relief well may intersect at a first side of the blowout, and a second relief well may intersect at a second side of the blowout well. Also, while FIG. 1 depicts the relief well intersecting the blowout well horizontally, example implementations may at any other angle (generally deviated).

### Example Computer

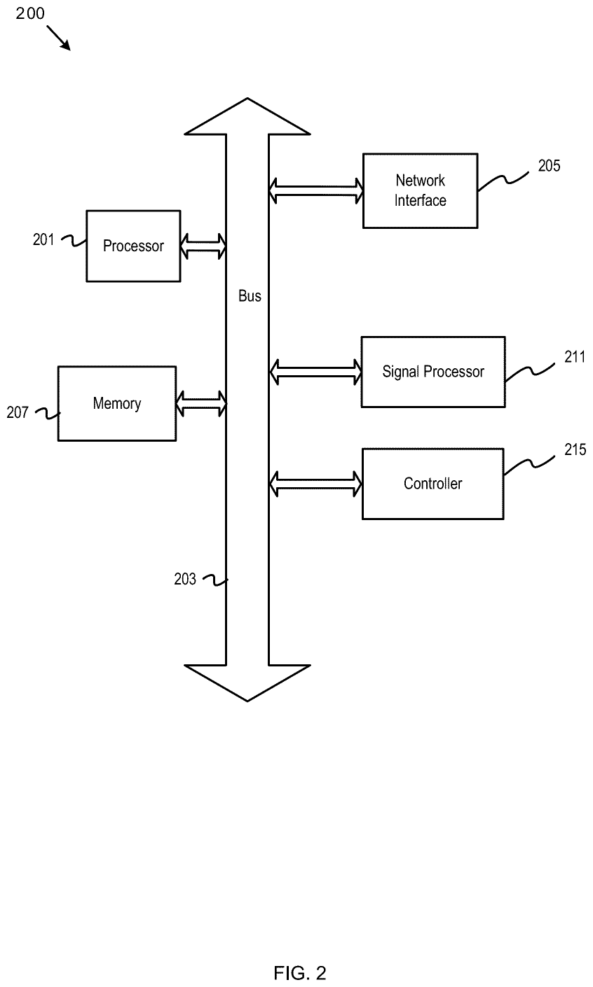

FIG. 2 is a block diagram of an example computer, according to some embodiments. FIG. 2 depicts a computer 200 that includes a processor 201 (possibly including multiple processors, multiple cores, multiple nodes, and/or implementing multi-threading, etc.). The computer 200 includes a memory 207. The memory 207 may be system memory or any one or more of the above already described possible realizations of machine-readable media. The computer 200 also includes a bus 203 and a network interface 205.

The computer 200 also includes a simulation processor 211 and a controller 215. The simulation processor 211 and the controller 215 may perform one or more of the operations described herein. For example, the signal processor 211 may perform processing to simulation a dynamic kill operation of a blowout well. The controller 215 may perform various control operations for performing a dynamic kill operation of a blowout well.

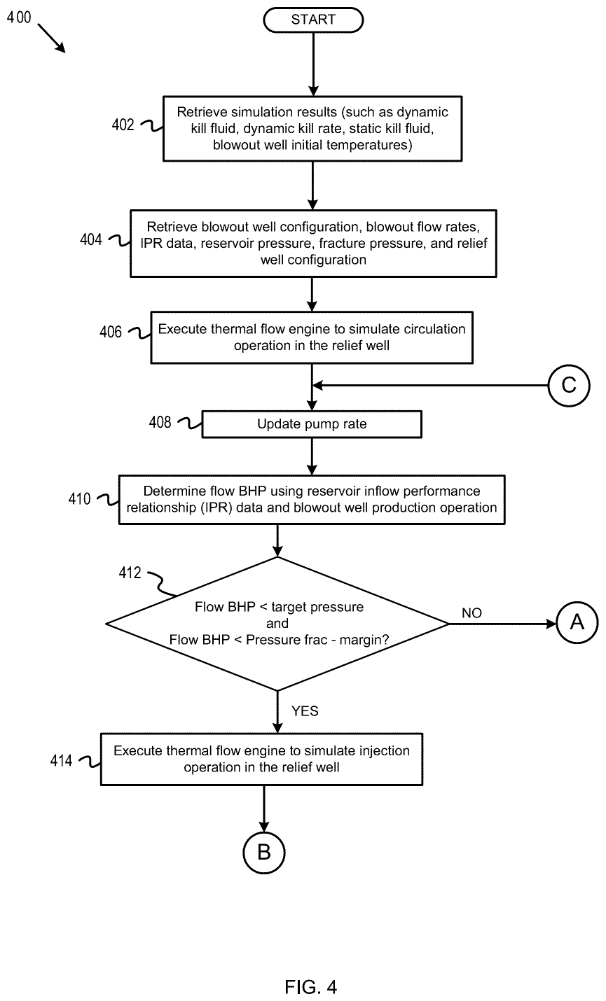

Any one of the previously described functionalities may be partially (or entirely) implemented in hardware and/or on the processor 201. For example, the functionality may be implemented with an application specific integrated circuit, in logic implemented in the processor 201, in a co-processor on a peripheral device or card, etc. Further, realizations may include fewer or additional components not illustrated in FIG. 4 (e.g., video cards, audio cards, additional network interfaces, peripheral devices, etc.). The processor 201 and the network interface 205 are coupled to the bus 203. Although illustrated as being coupled to the bus 203, the memory 207 may be coupled to the processor 201.

### Example Operations

Example operations for simulating a dynamic kill operation are now described.

Operations for Simulation of Flow BPH Vs. Time During a Dynamic Well Kill

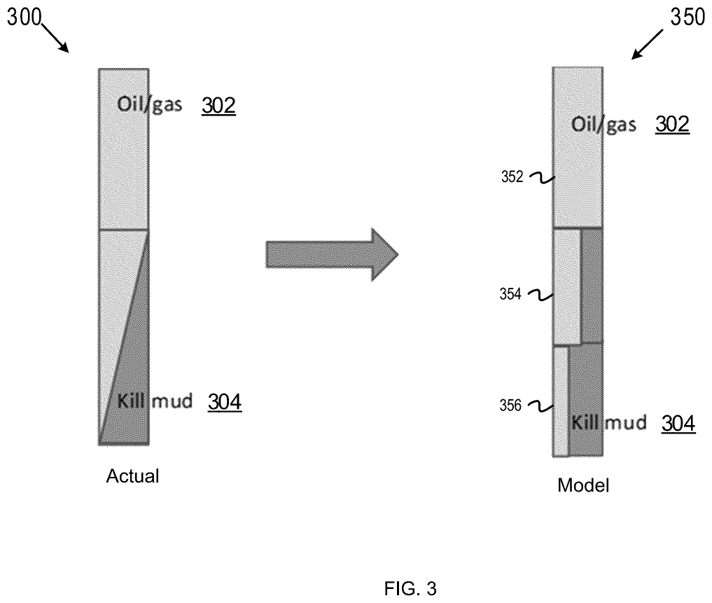

FIG. 3 is a diagram of an actual versus (vs.) model of mixed fluid elements in a blowout well during a dynamic well kill, according to some embodiments. FIG. 3 includes an actual model 300 and a real model 350 of the mixed fluid elements in a blowout well during a dynamic well kill. Both the actual model 300 and the real model 350 are depicted as columns having a fixed volume.

As shown, initially, the fluid elements in the blowout well include essentially just oil/gas 302. However, over time, the mixed fluid elements in the blowout well include an increase over time of a kill mud 304 (introduced via the relief well), while there is a decrease over time of the oil/gas 302. The column in the model 350 is separated into three discrete elements. A first element 352 includes fluid elements that are essentially only oil/gas 302. The second element 354 include fluid elements that are a mixture of oil/gas 302 and the kill mud 304. As shown, in this example, the oil/gas 302 and the kill mud 304 are approximately 60% and 40%, respectively, of the mixture of fluid elements in the second element 354. The third element 356 include fluid elements that are also a mixture of oil/gas 302 and the kill mud 304. As shown, in this example, the oil/gas 302 and the kill mud 304 are approximately 75% and 25%, respectively, of the mixture of fluid elements in the second element 356. Accordingly, over time, the kill mud 304 may replace the oil/gas 302 in the blowout well-thereby killing the blowout therein.

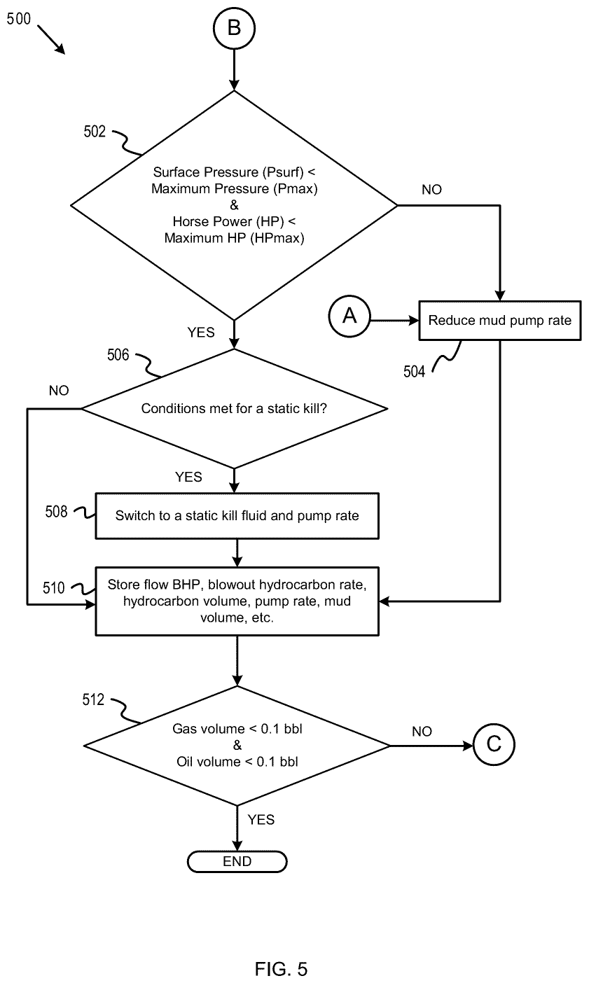

FIGS. 4-5 are flowcharts for simulating a flow bottom hole pressure (BHP) versus time during a dynamic well kill, according to some embodiments. Operations of flowcharts 400 and 500 of FIGS. 4-5, respectively, may be performed by software, firmware, hardware, or a combination thereof. Operations of the flowcharts 400-500 are first described and continue between each other through transition points A, B, and C. Operations of the flowcharts 400-500 are described in reference to FIGS. 1-2. However, other systems and components can be used to perform the operations now described. Operations of the flowchart 400 start at block 402.

At block 402, simulation results (such as dynamic kill fluid, dynamic kill rate, static kill fluid, blowout well initial temperatures) are retrieved. For example, with reference to FIG. 2, the processor 201 may retrieve the simulation results from a machine-readable medium (local and/or remote to the computer 200).

At block 404, blowout well configuration, blowout flow rates, IPR data, reservoir pressure, fracture pressure, and relief well configuration are retrieved. For example, with reference to FIG. 2, the processor 201 may retrieve this data from a machine-readable medium (local and/or remote to the computer 200).

At block 406, a thermal flow engine to simulate circulation operation in the relief well is executed. For example, with reference to FIG. 2, the processor 201 may perform this operation. Such a simulation may simulate the cooling down effect in the relief well-because the kill mud or fluid may be much lower than the temperature downhole in the relief well. Accordingly, this may result in the cooling down of the relief well.

At block 408, the pump rate of the kill mud down into the relief well is updated. For example, with reference to FIG. 2, the processor 201 may perform this update. In particular, this pump rate may vary over time.

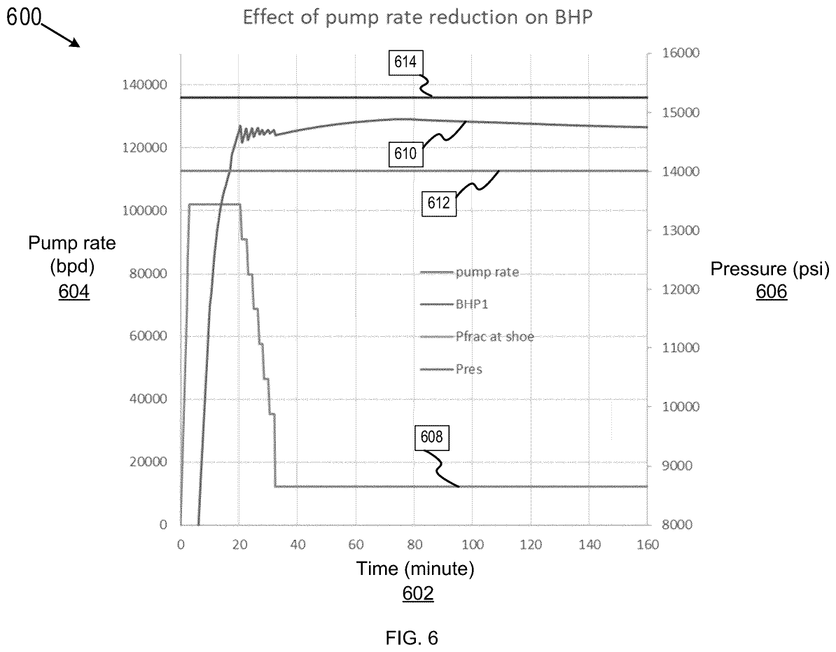

To illustrate, FIG. 6 is a graph depicting a flow BHP vs. time and pump rate vs. time during a dynamic well kill, according to some embodiments. In particular, FIG. 6 depicts a graph 600 that includes an x-axis 602 (which is time (minutes)) and a first y-axis 604 (which is a pump rate (barrels per day (bpd))), a second y-axis 606 (which is pressure (pounds per square inch (psi)). The graph 600 includes a plot 608 that is the pump rate of the kill mud being pumped downhole via the relief well into the blowout well. The graph 600 also includes a plot 610 that is the bottom hole pressure (BHP1) in the relief well and the blowout well. The graph 600 includes plots 612 and 614. The plot 612 is a minimum pressure needed to dynamically kill the blowout well. The plot 614 is a minimum pressure that will result in fracturing in the surrounding subsurface formation downhole in the relief well and the blowout well. Accordingly, the BHP1 should be a pressure between the plots 612 and 614 in order to kill the blowout of the blowout well but not exceed a pressure that would cause fracturing in the surrounding subsurface formation (thereby damaging the wells from the fracturing. In this example, the pump rate is updated over time such that initially the pump rate increases very quickly (this is the dynamic kill rate to stop the blowout quickly to quickly reduce impact to the environment. The pump rate then plateaus, followed by a decrease very quickly, followed by a substantially constant rate. As shown, this substantially constant rate coincides with the point in time where the BHP1 levels out between the plots 612 and 614. This substantially constant rate coincides with the static kill.

Returning to the description of FIG. 4, operations of the flowchart 400 continue at block 410.

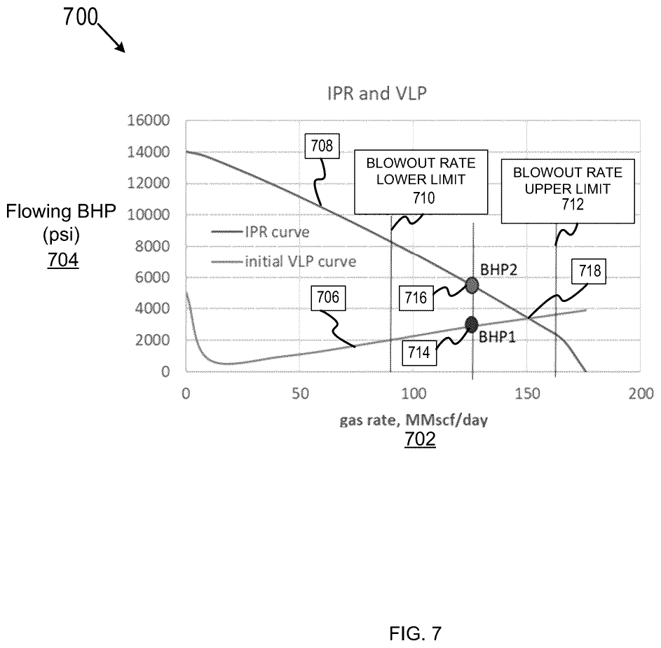

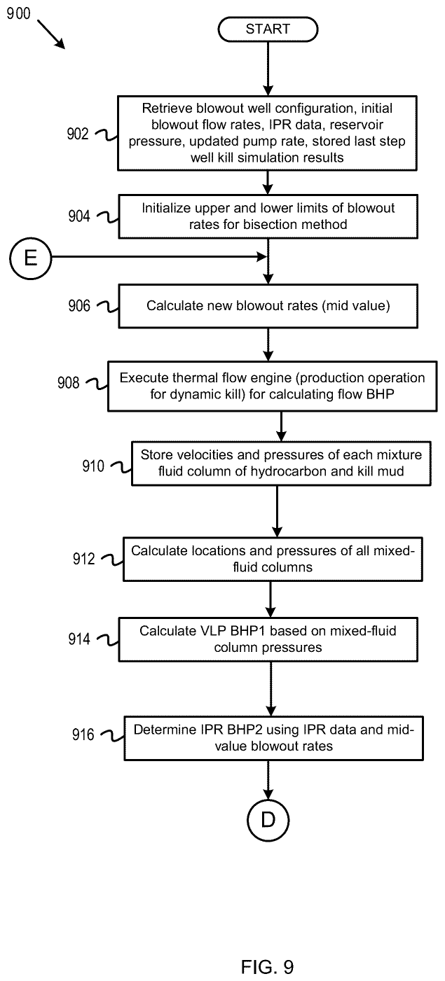

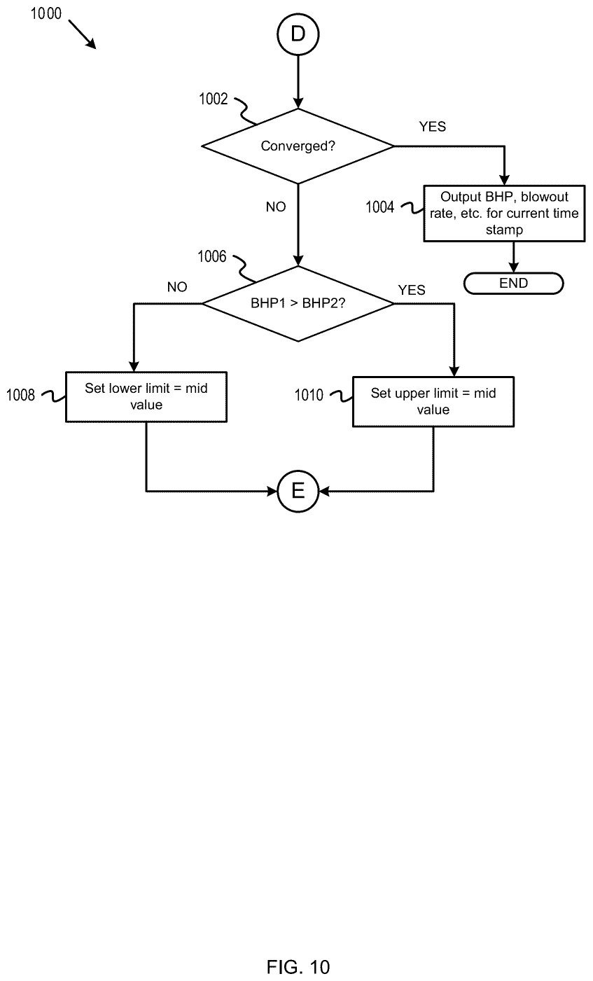

At block 410, the flow BHP is determined using reservoir inflow performance relationship (IPR) data and blowout well production operation. For example, with reference to FIG. 2, the processor 201 may make this determination. An example of the operations to determine the flow BHP is described below in reference to a graph 700 of FIG. 7 and the flowcharts 900-1000 of FIGS. 9-10.

At block 412, a determination is made of whether the flow BHP is less than a target pressure and whether the flow BHP is less than a pressure that results in fracturing the surrounding subsurface formation (Pressure_{frac})—a margin. For example, with reference to FIG. 2, the processor 201 may make these determinations. If the flow BHP is less than a target pressure and the flow BHP is less than a Pressure_{frac}—a margin, operations of the flowchart 300 continue at block 314. Otherwise, operations of the flowchart 400 continue at transition point A, which continues at transition point A of the flowchart 500, which continues at block 504 (which is further described below).

At block 414, the thermal flow engine is executed to simulate injection operation in the relief well. For example, with reference to FIG. 2, the processor 201 may perform this operation. Operations of the flowchart 400 continue at transition point B, which continues at transition point B of the flowchart 500.

Operations of the flowchart 500 are now described. In the flowchart 500, from transition B, operations continue at block 502.

At block 502, a determination is made of whether the surface pressure (P_{surf}) (at the relief well) is less than a maximum pressure (Pₘₐₓ) and whether the horse power (HP) of the pump (pumping the kill mud down into the relief well) is less than a maximum HP (HP max) for the pump. For example, with reference to FIG. 2, the processor 201 may this determination. If P_{surf} is not less than Pₘₐₓ or the HP not less than HPₘₐₓ, operations of the flowchart 500 continue at block 504. Otherwise, operations of the flowchart 500 continue at block 506.

At block 504, the mud pump rate is reduced. For example, with reference to FIG. 2, the processor 201 may reduce the mud pump rate. Operations of the flowchart 500 continue at block 510 (which is further described below).

At block 506, a determination is made of whether conditions for a static kill are met. For example, with reference to FIG. 2, the processor 201 may make this determination. In some implementations, the conditions for a static kill may include the following: 1) the BHP is greater than the reservoir pressure and 2) one or more special conditions. For example, the special conditions may include a) the gas volume is less than 1.0 bbl and the oil volume is less than 1.0 bbl, b) gas dominated and |pump rate−prev. pump rate|<0.1, and c) oil dominated & BHP>target pressure. If the conditions for a static kill are met, operations of the flowchart 500 continue at block 508. Otherwise, operations of the flowchart 500 continue at block 510 (which is further described below).

At block 508, a switch is made to a static kill fluid and pump rate. For example, with reference to FIG. 2, the processor 201 may perform this switch to a static kill.

At block 510, the flow BHP, blowout hydrocarbon rate, hydrocarbon volume, pump rate, mud volume, etc. are stored. For example, with reference to FIG. 2, the processor 201 may perform this storage. For instance, the processor 201 may store this data in a machine-readable medium (local and/or remote to the computer 200). This data may be stored for each time stamp.

At block 512, a determination is made of whether a gas volume being output at the surface of the blowout well is less than a minimum gas threshold (such as 0.1 barrels (bbl)) and whether the oil volume being output at the surface of the blowout well is less than a minimum oil threshold (such as 0.1 bbl). For example, with reference to FIG. 2, the processor 201 may make this determination. If the gas volume being output at the surface of the blowout well is not less than the minimum gas threshold (such as 0.1 bbl) or the oil volume being output at the surface of the blowout well is not less than a minimum oil threshold (such as 0.1 bbl), operations of the flowchart 500 continue at transition point C (which continues at transition point C of the flowchart 400 of FIG. 4—which continues at block 308 where the pump rate is updated). If the gas volume being output at the surface of the blowout well is less than the minimum gas threshold (such as 0.1 bbl) and the oil volume being output at the surface of the blowout well is less than a minimum oil threshold (such as 0.1 bbl), operations of the flowchart 500 are complete.

### Operations for Determining a Flow BHP Using IPR and VLP Curves

Operations for determining a flow BHP using IPR and VLP curves are now described.

FIG. 7 is a graph depicting a gas rate vs. a flowing BHP during a simulation of a dynamic well kill, according to some embodiments. FIG. 7 depicts a graph 700 that includes an x-axis 502 that is a flowing BHP (pounds per square inch (psi)) and a y-axis 704 that is a gas rate (million standard cubic feet per day (MMscf/day)). The graph 700 includes an initial vertical lift performance (VLP) curve 706 of the blowout well. The VLP curve 706 may be a function of the structure of blowout well. The graph 700 also includes an inflow performance relationship (IPR) curve 708 of the reservoir flow flowing into the blowout well from the surrounding subsurface formation. The IPR curve 708 may be a function of the properties of the reservoir and a diameter of the blowout well. The graph 700 also defines a blowout rate lower limit 710 at approximately 90 MMscf/day and a blowout rate upper limit 712 at approximately 162 MMscf/day. The graph 700 also includes an intersection point 718 where the VLP curve 706 and the IPR curve 708 intersect. The VLP curve 706 may move during the blowout of the blowout well so the intersection 718 may change.

In a first step, the flow BHP may be estimated based on the equilibrium of reservoir fluid in-flow (IPR) and wellbore vertical lift (VLP), as shown in FIG. 7. This estimation of the flow BHP may create a pressure profile. The VLP may be simulated by executing the thermal flow engine using given kill mud flow rate and to-be-determine blowout oil/gas rates.

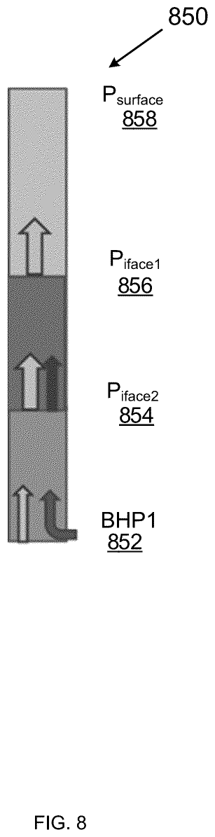

In a second step, mud-front pressure Piface may be obtained by interpolation using the pressure profile (created above). To illustrate, FIG. 8 is a diagram of a model of the pressure of blowout well during a dynamic well kill, according to some embodiments. FIG. 8 includes a model 800 of the pressure is separated into three discrete elements. A first element is defined between a BHP1 852 and a P_{iface2} 854. A second element is defined between the P_{iface2} 854 and a P_{iface1} 856. A third element is defined between P_{iface1} 856 and a P_{surface} 858.

In a third step, the dP1 (mud-front MD to intercept MD) may be calculated. BHP1 equals Piface+dP1.

In a fourth step, using the IPR data and the same oil/gas flow rate used in step 1 (above), another bottomhole pressure BHP2 may be obtained. If there is no IPR data table, then a linear IPR relationship may be assumed using the initial flow bottomhole pressure, initial blowout rates and reservoir pressure.

In a fifth step, a bisection method may be used to find a solution of oil/gas flow rates for the current time step with the converge criteria: |BHP1−BHP2|<EPS.

To further illustrate determining a flow BHP, FIGS. 9-10 are flowcharts for determining a flow BHP using IPR data and a blowout well production operation, according to some embodiments. Operations of flowcharts 900 and 1000 of FIGS. 9-10, respectively, may be performed by software, firmware, hardware, or a combination thereof. Operations of the flowcharts 900-1000 are then described and continue between each other through transition points D and E. Operations of the flowcharts 900-1000 are described in reference to FIGS. 1-2. However, other systems and components can be used to perform the operations now described. In some implementations, operations of the flowcharts 900-1000 include a bisection method to arrive at the solution (to determine the point of intersection of the VLP curve with the IPR curve for each time step). Operations of the flowchart 900 start at block 902.

At block 902, blowout well configuration, initial blowout flow rates, IPR data, reservoir pressure, updated pump rate, and stored last step well kill simulation results are retrieved. For example, with reference to FIG. 2, the processor 201 may retrieve this data (local and/or remote to the computer 200).

At block 904, upper and lower limits of blowout rates for a bisection method are initialized. For example, with reference to FIG. 2, the processor 201 may perform this operation.

At block 906, new blowout rates (mid value) are calculated. For example, with reference to FIG. 2, the processor 201 may perform this operation.

At block 908, the thermal flow engine (production operation for dynamic kill) for calculating flow BHP is executed. For example, with reference to FIG. 2, the processor 201 may perform this operation.

At block 910, velocities and pressures of each mixture fluid column of hydrocarbon and kill mud are stored. For example, with reference to FIG. 2, the processor 201 may perform this operation.

At block 912, locations and pressures of all mixed-fluid columns are calculated. For example, with reference to FIG. 2, the processor 201 may perform this operation.

At block 914, the VLP BHP1 is calculated based on mixed-fluid column pressures. For example, with reference to FIG. 2, the processor 201 may perform this operation.

At block 916, the IPR BHP2 is determined using IPR data and mid-value blowout rates. For example, with reference to FIG. 2, the processor 201 may perform this operation. Operations of the flowchart 900 continue at transition point D (which continues at transition point D of the flowchart 1000.

Operations of the flowchart 1000 are now described. From transition point D, operations continue at block 1002.

At block 1002, a determination is made of whether BHP1 and BHP2 have converged. For example, with reference to FIG. 2, the processor 201 may make this determination. If the BHP1 and BHP2 have converged, operations of the flowchart 1000 continue at block 1004. Otherwise, operations of the flowchart 1000 continue at block 1006 (which is further described below).

At block 1004, BHP, blowout rate, etc. for current time stamp is output. For example, with reference to FIG. 2, the processor 201 may perform this operation. Operations of the flowchart 1000 are then complete.

At block 1006, a determination is made of whether BHP1 is greater than BHP2. For example, with reference to FIG. 2, the processor 201 may make this determination. If BHP1 is not greater than BHP2, operations of the flowchart 1000 continue at block 1008. Otherwise, operations of the flowchart 1000 continue at block 1010.

At block 1008, the lower limit is set to the mid value. For example, with reference to FIG. 2, the processor 201 may perform this operation. Operations of the flowchart 1000 continue at transition point E (which continues at transition point E of the flowchart 900—which continues at block 906).

At block 1010, the upper limit is set to the mid value. For example, with reference to FIG. 2, the processor 201 may perform this operation. Operations of the flowchart 1000 continue at transition point E (which continues at transition point E of the flowchart 900—which continues at block 906).

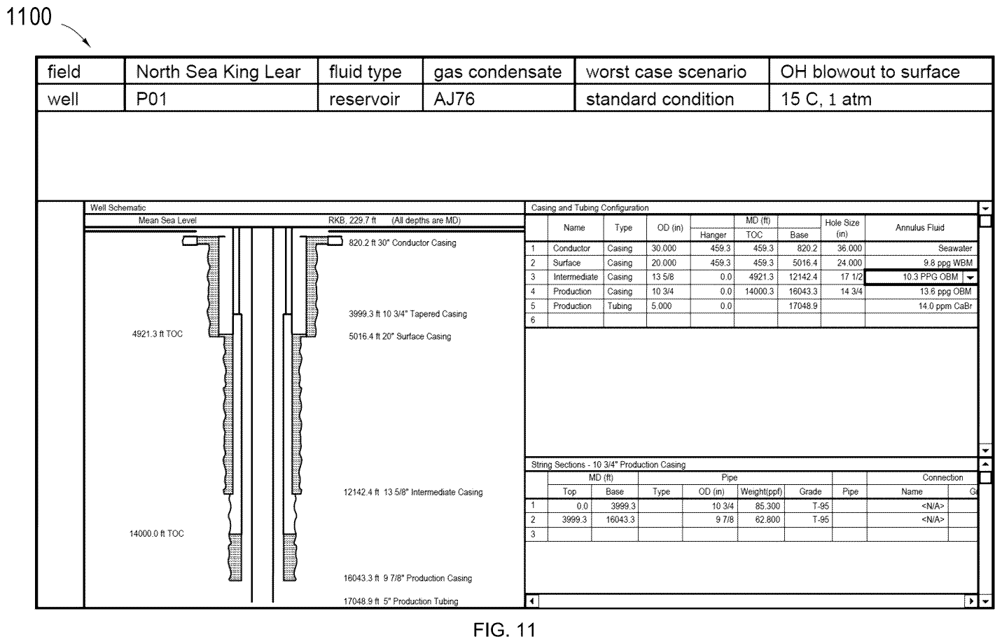

FIG. 11 is an example of a graphical user interface (GUI) of an example data for a blowout well configuration, according to some embodiments. In particular, FIG. 11 depicts a GUI 1100 that includes example data for a blowout well configuration for an open hole blowout to surface.

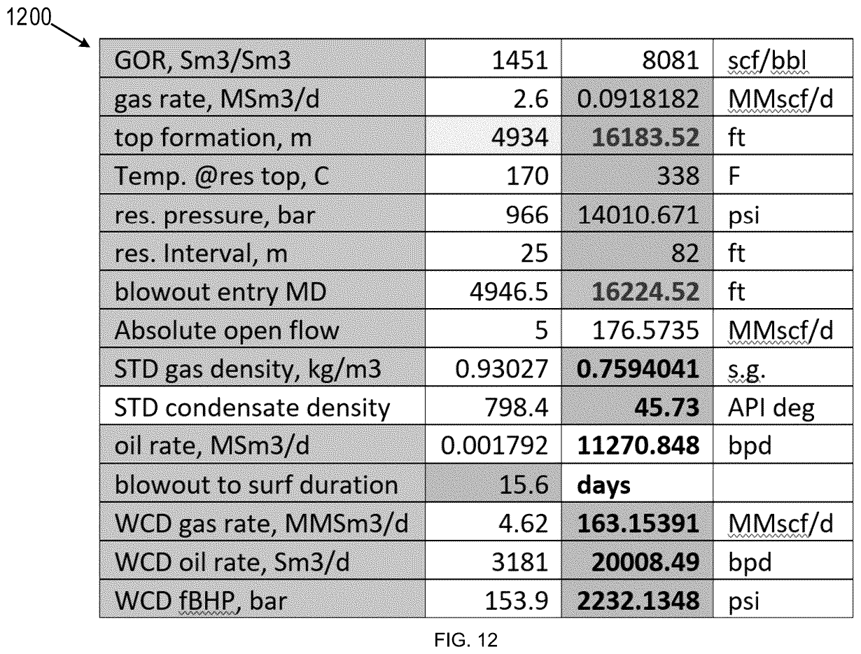

FIG. 12 is a table of example parameters for a dynamic kill operation, according to some embodiments. FIG. 12 includes a table 1200 of example parameters and values for a dynamic kill operation.

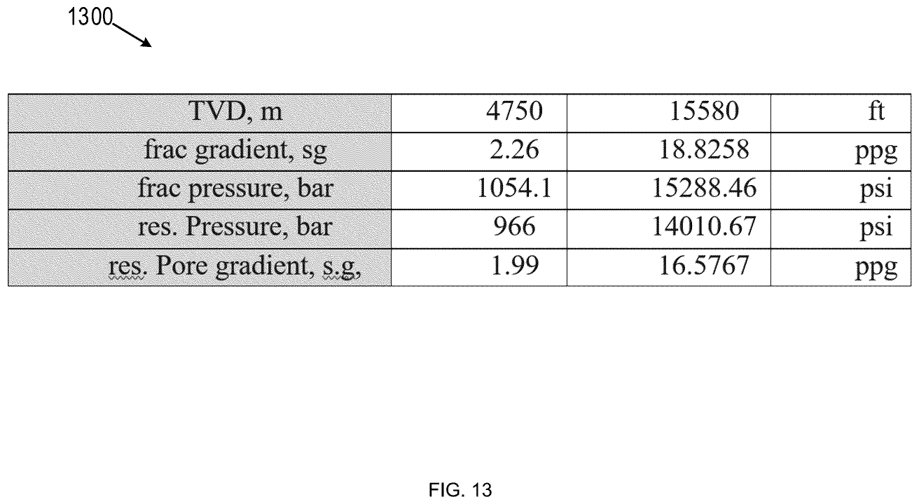

FIG. 13 is a table of example attributes of the reservoir, according to some embodiments. FIG. 13 includes a table 1300 of example attributes and values of the reservoir that is surrounding the blowout well.

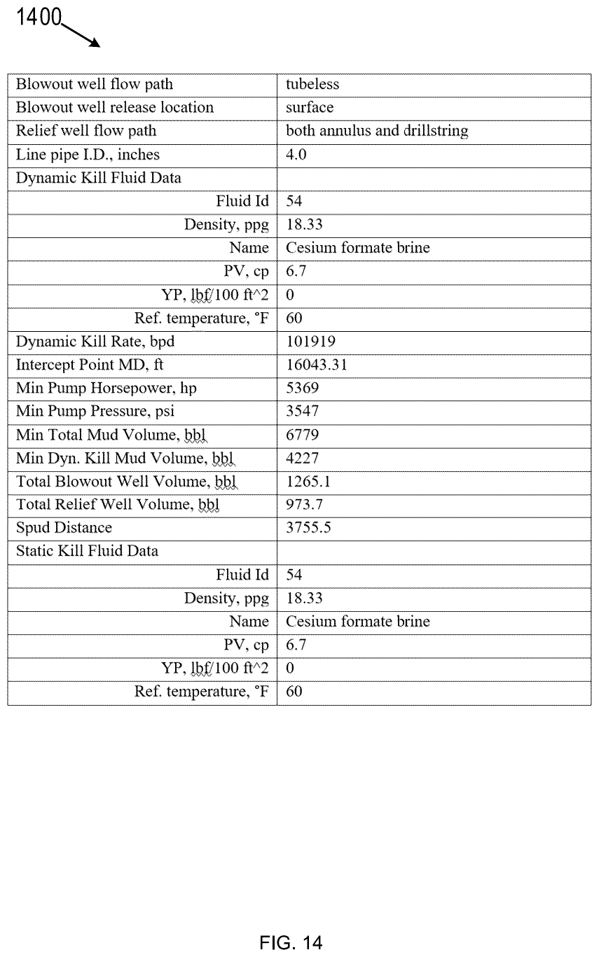

FIG. 14 is an example summary table of a well kill solution, according to some embodiments. FIG. 14 includes a table 1400 that includes a column of parameters and/or attributes of an example well kill solution and a column of example values of such parameters and/or attributes.

While the aspects of the disclosure are described with reference to various implementations and exploitations, it will be understood that these aspects are illustrative and that the scope of the claims is not limited to them. Many variations, modifications, additions, and improvements are possible. Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

The flowcharts are provided to aid in understanding the illustrations and are not to be used to limit scope of the claims. The flowcharts depict example operations that can vary within the scope of the claims. Additional operations may be performed; fewer operations may be performed; the operations may be performed in parallel; and the operations may be performed in a different order. It will be understood that each block of the flowchart illustrations and/or block diagrams, and combinations of blocks in the flowchart illustrations and/or block diagrams, can be implemented by program code. The program code may be provided to a processor of a general-purpose computer, special purpose computer, or other programmable machine or apparatus.

Use of the phrase “at least one of” preceding a list with the conjunction “and” should not be treated as an exclusive list and should not be construed as a list of categories with one item from each category, unless specifically stated otherwise. A clause that recites “at least one of A, B, and C” can be infringed with only one of the listed items, multiple of the listed items, and one or more of the items in the list and another item not listed.

As will be appreciated, aspects of the disclosure may be embodied as a system, method or program code/instructions stored in one or more machine-readable media. Accordingly, aspects may take the form of hardware, software (including firmware, resident software, micro-code, etc.), or a combination of software and hardware aspects that may all generally be referred to herein as a “circuit,” “module” or “system.” The functionality presented as individual modules/units in the example illustrations can be organized differently in accordance with any one of platform (operating system and/or hardware), application ecosystem, interfaces, programmer preferences, programming language, administrator preferences, etc.

Any combination of one or more machine-readable medium(s) may be utilized. The machine-readable medium may be a machine-readable signal medium or a machine-readable storage medium. A machine-readable storage medium may be, for example, but not limited to, a system, apparatus, or device, that employs any one of or combination of electronic, magnetic, optical, electromagnetic, infrared, or semiconductor technology to store program code. More specific examples (a non-exhaustive list) of the machine-readable storage medium would include the following: a portable computer diskette, a hard disk, a random-access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a machine-readable storage medium may be any tangible medium that can contain or store a program for use by or in connection with an instruction execution system, apparatus, or device. A machine-readable storage medium is not a machine-readable signal medium.

A machine-readable signal medium may include a propagated data signal with machine readable program code embodied therein, for example, in baseband or as part of a carrier wave. Such a propagated signal may take any of a variety of forms, including, but not limited to, electro-magnetic, optical, or any suitable combination thereof. A machine-readable signal medium may be any machine-readable medium that is not a machine-readable storage medium and that can communicate, propagate, or transport a program for use by or in connection with an instruction execution system, apparatus, or device. Program code embodied on a machine-readable medium may be transmitted using any appropriate medium, including but not limited to wireless, wireline, optical fiber cable, RF, etc., or any suitable combination of the foregoing.

Computer program code for carrying out operations for aspects of the disclosure may be written in any combination of one or more programming languages, including an object oriented programming language such as the Java® programming language, C++ or the like; a dynamic programming language such as Python; a scripting language such as Perl programming language or PowerShell script language; and conventional procedural programming languages, such as the “C” programming language or similar programming languages. The program code may execute entirely on a stand-alone machine, may execute in a distributed manner across multiple machines, and may execute on one machine while providing results and or accepting input on another machine.

The program code/instructions may also be stored in a machine-readable medium that can direct a machine to function in a particular manner, such that the instructions stored in the machine-readable medium produce an article of manufacture including instructions which implement the function/act specified in the flowchart and/or block diagram block or blocks.

While the aspects of the disclosure are described with reference to various implementations and exploitations, it will be understood that these aspects are illustrative and that the scope of the claims is not limited to them. Many variations, modifications, additions, and improvements are possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

### EXAMPLE EMBODIMENTS

Embodiment #1: A method comprising: retrieving attributes of a blowout well and a relief well; and simulating a dynamic kill of a blowout from the blowout well via a kill mud pumped down through the relief well, wherein the simulating comprises determining a flowing bottom hole pressure for the blowout well and the relief well based on an intersection of a reservoir inflow performance relationship (IPR) curve and a wellbore vertical lift (VLP) curve.

Embodiment #2: The method of Embodiment #1, wherein the simulating comprises, simulating flow circulation in the relief well based on the attributes; and simulating the flowing bottom hole pressure versus time.

Embodiment #3: The method of Embodiment #2, wherein the simulating comprises simulating a blowout flow rate.

Embodiment #4: The method of Embodiment #3, wherein the simulating comprises simulating a pump rate of the kill mud via the relief well.

Embodiment #5: The method of Embodiment #1, wherein simulating the dynamic kill comprises determining a pump rate of the kill mud such that a bottom hole pressure is within a range that is between a minimum pressure to initiate killing of the blowout of the blowout well and a maximum pressure that is a pressure that causes fracturing in a subsurface formation surrounding at least one of the relief well or the blowout well.

Embodiment #6: The method of Embodiment #1, further comprising: designing the relief wellbore to be drilled based on the simulation; and drilling the relief wellbore based on the design to connect the relief wellbore to the blowout wellbore.

Embodiment #7: The method of Embodiment #1, further comprising: setting at least one operation parameter of an actual kill of the blowout well using the relief well based on the simulation.

Embodiment #8: The method of Embodiment #7, wherein the at least one operation parameter comprises at least one of flowing bottom hole pressure, blowout flow rate, and pump rate of kill mud via the relief well.

Embodiment #9: A non-transitory, computer-readable medium having instructions stored thereon that are executable by a processor, the instructions comprising: instructions to retrieve attributes of a blowout well and a relief well; and instructions to simulate a dynamic kill of a blowout from the blowout well via a kill mud pumped down through the relief well, wherein the simulating comprises determining a flowing bottom hole pressure for the blowout well and the relief well based on an intersection of a reservoir inflow performance relationship (IPR) curve and a wellbore vertical lift (VLP) curve.

Embodiment #10: The non-transitory, computer-readable medium of Embodiment #9, wherein the instructions comprise, instructions to simulate flow circulation in the relief well based on the attributes; and instructions to simulate the flowing bottom hole pressure versus time, a blowout flow rate, and a pump rate of the kill mud via the relief well.

Embodiment #11: The non-transitory, computer-readable medium of Embodiment #9, wherein the instructions to simulate the dynamic kill comprises instructions to determine a pump rate of the kill mud such that a bottom hole pressure is within a range that is between a minimum pressure to initiate killing of the blowout of the blowout well and a maximum pressure that is a pressure that causes fracturing in a subsurface formation surrounding at least one of the relief well or the blowout well.

Embodiment #12: The non-transitory, computer-readable medium of Embodiment #9, wherein the instructions comprise, instructions to design the relief wellbore to be drilled based on the simulation; and instructions to drill the relief wellbore based on the design to connect the relief wellbore to the blowout wellbore.

Embodiment #13: The non-transitory, computer-readable medium of Embodiment #9, wherein the instructions comprise, instructions to set at least one operation parameter of an actual kill of the blowout well using the relief well based on the simulation.

Embodiment #14: The non-transitory, computer-readable medium of Embodiment #13, wherein the at least one operation parameter comprises at least one of flowing bottom hole pressure, blowout flow rate, and pump rate of kill mud via the relief well.

Embodiment #15: An apparatus comprising: a processor; and a computer-readable medium having instructions stored thereon that are executable by the processor to cause the processor to, retrieve attributes of a blowout well and a relief well; and simulate a dynamic kill of a blowout from the blowout well via a kill mud pumped down through the relief well, wherein the simulating comprises determining a flowing bottom hole pressure for the blowout well and the relief well based on an intersection of a reservoir inflow performance relationship (IPR) curve and a wellbore vertical lift (VLP) curve.

Embodiment #16: The apparatus of Embodiment #15, wherein the instructions comprise instructions executable by the processor to cause the processor to, simulate flow circulation in the relief well based on the attributes; and simulate the flowing bottom hole pressure versus time, a blowout flow rate, and a pump rate of the kill mud via the relief well.

Embodiment #17: The apparatus of Embodiment #15, wherein the instructions executable by the processor to cause the processor to simulate the dynamic kill comprises instructions executable by the processor to cause the processor to determine a pump rate of the kill mud such that a bottom hole pressure is within a range that is between a minimum pressure to initiate killing of the blowout of the blowout well and a maximum pressure that is a pressure that causes fracturing in a subsurface formation surrounding at least one of the relief well or the blowout well.

Embodiment #18: The apparatus of Embodiment #15, wherein the instructions comprise instructions executable by the processor to cause the processor to, design the relief wellbore to be drilled based on the simulation; and drill the relief wellbore based on the design to connect the relief wellbore to the blowout wellbore.

Embodiment #19: The apparatus of Embodiment #15, wherein the instructions comprise instructions executable by the processor to cause the processor to, set at least one operation parameter of an actual kill of the blowout well using the relief well based on the simulation.

Embodiment #20: The apparatus of Embodiment #19, wherein the at least one operation parameter comprises at least one of flowing bottom hole pressure, blowout flow rate, and pump rate of kill mud via the relief well.

1. A method comprising:
retrieving attributes of a blowout well and a relief well; and
simulating a dynamic kill of a blowout from the blowout well via a kill mud pumped down through the relief well, wherein the simulating comprises determining a flowing bottom hole pressure for the blowout well and the relief well based on an intersection of a reservoir inflow performance relationship (IPR) curve and a wellbore vertical lift (VLP) curve.

2. The method of claim 1, wherein the simulating comprises,
simulating flow circulation in the relief well based on the attributes; and
simulating the flowing bottom hole pressure versus time.

3. The method of claim 2, wherein the simulating comprises simulating a blowout flow rate.

4. The method of claim 3, wherein the simulating comprises simulating a pump rate of the kill mud via the relief well.

5. The method of claim 1, wherein simulating the dynamic kill comprises determining a pump rate of the kill mud such that a bottom hole pressure is within a range that is between a minimum pressure to initiate killing of the blowout of the blowout well and a maximum pressure that is a pressure that causes fracturing in a subsurface formation surrounding at least one of the relief well or the blowout well.

6. The method of claim 1, further comprising:
designing the relief wellbore to be drilled based on the simulation; and
drilling the relief wellbore based on the design to connect the relief wellbore to the blowout wellbore.

7. The method of claim 1, further comprising:
setting at least one operation parameter of an actual kill of the blowout well using the relief well based on the simulation.

8. The method of claim 7, wherein the at least one operation parameter comprises at least one of flowing bottom hole pressure, blowout flow rate, and pump rate of kill mud via the relief well.

9. A non-transitory, computer-readable medium having instructions stored thereon that are executable by a processor, the instructions comprising:
instructions to retrieve attributes of a blowout well and a relief well; and
instructions to simulate a dynamic kill of a blowout from the blowout well via a kill mud pumped down through the relief well, wherein the simulating comprises determining a flowing bottom hole pressure for the blowout well and the relief well based on an intersection of a reservoir inflow performance relationship (IPR) curve and a wellbore vertical lift (VLP) curve.

10. The non-transitory, computer-readable medium of claim 9, wherein the instructions comprise,
instructions to simulate flow circulation in the relief well based on the attributes; and
instructions to simulate the flowing bottom hole pressure versus time, a blowout flow rate, and a pump rate of the kill mud via the relief well.

11. The non-transitory, computer-readable medium of claim 9, wherein the instructions to simulate the dynamic kill comprises instructions to determine a pump rate of the kill mud such that a bottom hole pressure is within a range that is between a minimum pressure to initiate killing of the blowout of the blowout well and a maximum pressure that is a pressure that causes fracturing in a subsurface formation surrounding at least one of the relief well or the blowout well.

12. The non-transitory, computer-readable medium of claim 9, wherein the instructions comprise,
instructions to design the relief wellbore to be drilled based on the simulation; and
instructions to drill the relief wellbore based on the design to connect the relief wellbore to the blowout wellbore.

13. The non-transitory, computer-readable medium of claim 9, wherein the instructions comprise,
instructions to set at least one operation parameter of an actual kill of the blowout well using the relief well based on the simulation.

14. The non-transitory, computer-readable medium of claim 13, wherein the at least one operation parameter comprises at least one of flowing bottom hole pressure, blowout flow rate, and pump rate of kill mud via the relief well.

15. An apparatus comprising:
a processor; and
a computer-readable medium having instructions stored thereon that are executable by the processor to cause the processor to,
retrieve attributes of a blowout well and a relief well; and
simulate a dynamic kill of a blowout from the blowout well via a kill mud pumped down through the relief well, wherein the simulating comprises determining a flowing bottom hole pressure for the blowout well and the relief well based on an intersection of a reservoir inflow performance relationship (IPR) curve and a wellbore vertical lift (VLP) curve.

16. The apparatus of claim 15, wherein the instructions comprise instructions executable by the processor to cause the processor to,
simulate flow circulation in the relief well based on the attributes; and
simulate the flowing bottom hole pressure versus time, a blowout flow rate, and a pump rate of the kill mud via the relief well.

17. The apparatus of claim 15, wherein the instructions executable by the processor to cause the processor to simulate the dynamic kill comprises instructions executable by the processor to cause the processor to determine a pump rate of the kill mud such that a bottom hole pressure is within a range that is between a minimum pressure to initiate killing of the blowout of the blowout well and a maximum pressure that is a pressure that causes fracturing in a subsurface formation surrounding at least one of the relief well or the blowout well.

18. The apparatus of claim 15, wherein the instructions comprise instructions executable by the processor to cause the processor to,
design the relief wellbore to be drilled based on the simulation; and
drill the relief wellbore based on the design to connect the relief wellbore to the blowout wellbore.

19. The apparatus of claim 15, wherein the instructions comprise instructions executable by the processor to cause the processor to,
set at least one operation parameter of an actual kill of the blowout well using the relief well based on the simulation.

20. The apparatus of claim 19, wherein the at least one operation parameter comprises at least one of flowing bottom hole pressure, blowout flow rate, and pump rate of kill mud via the relief well.
